(19) United States
(12) Patent Application Publication
(10) Pub. No.: US 2020/0187365 A1
(43) Pub. Date: Jun. 11, 2020

(54) METHOD FOR 3D-SHAPED MULTIPLE-LAYERED ELECTRONICS WITH ULTRASONIC VOXEL MANUFACTURING

(71) Applicant: Interlog Corporation, Anaheim, CA (US)

(72) Inventors: Nathanael K. KIM, Anaheim, CA (US); Jason G. Park, Anaheim, CA (US); Justin Kwon, Anaheim, CA (US)

(73) Assignee: Interlog Corporation, Anaheim, CA (US)

(21) Appl. No.: 16/706,622

(22) Filed: Dec. 6, 2019

Related U.S. Application Data
(60) Provisional application No. 62/777,006, filed on Dec. 7, 2018.

(51) Int. Cl. H05K 3/40; H05K 3/04

(52) U.S. Cl. CPC H05K 3/4038; H05K 3/043

(57) ABSTRACT

A method for printing electrically conductive traces on a non-conductive material includes: printing a conductive material onto a non-conductive material by transferring ultrasonic energy to the conductive material; forming non-conductive resin on the non-conductive material on which the conductive material has been printed, using a three-dimensional printer head, the non-conductive resin being (or serving as) an insulation component, or placing a prepreg on the non-conductive material on which the conductive material has been printed; and forming a connecting portion or via hole in the non-conductive resin or the prepreg.

### CROSS REFERENCE TO RELATED APPLICATIONS

Pursuant to 35 U.S.C. § 119(e), this application claims the benefit of Provisional Application No. 62/777,006 filed on Dec. 7, 2018, the contents of which are hereby incorporated by reference herein in their entirety.

### BACKGROUND

### Technical Field

The present application relates to printing electrically conductive traces by applying ultrasonic energy to a conductive material. The present application also relates to a multiple-layered printed circuit board (PCB) fabrication process using ultrasonic energy for two (2)- and three (3)-dimensional (3D) PCB structures. In particular, the present application relates to an ultrasonic method for printing electrical patterns onto a PCB without employing a chemical or heating process.

### Background

In general, PCB fabrication includes a “build-Up method” and a “stack-up method.” A typical “build-up method” for PCB fabrication includes a cycle of drilling on a copper clad laminate (CCL), etching, dry film, inner layer exposing, and developing, the etching process requiring use of hazardous chemicals. A typical “stack-up method” for PCB fabrication includes a printing and etching process, silk screening or photo-printing using a resist on the CCL, and removal of the resist after completing the etching, requiring use of various solvents and chemicals. Increasingly stringent environmental regulations make use and disposal of solvents and chemicals difficult and expensive. Thus, there is a need for a flexible method for fabricating PCBs, not requiring multiple steps such as printing and etching processes, while providing traces with suitable electrical conductivity. Recently, conductive-ink based PCB printing on an insulation substrate has been developed. However, the conductive inks always contain a solvent that causes impurity, resulting in high resistivity even if silver is used, for example, 10 times higher than conventional copper PCBs.

According to at least one embodiment of the present invention, the present application provides a method and apparatus for fabricating PCBs that enables 2D and 3D electrical patterns (traces) with multiple-layered, 3D-shaped construction without using chemical treatment or other cumbersome processes used in the conventional PCB fabrication method(s). Disclosed in the present application are vibrational energy-transfer devices and processes for providing electrical patterns, vias between layers, insulation layers or coating, silk screen, masking, electrical connection (bonding, reflowing and soldering) to external electric elements, localized packaging for an electrical element, and a designated part during PCB fabrication. The devices and processes disclosed in the present application with reference to various embodiments eliminate complexity and environmental hazards raised in conventional chemical etching/plating processes. The inventive process according to various embodiments may reduce time and cost significantly, thus allowing (or facilitating) more effective PCB fabrication.

### SUMMARY OF THE INVENTION

According to at least one embodiment of the present invention, a method for printing electrically conductive traces on a non-conductive material includes: printing a conductive material onto a non-conductive material by transferring ultrasonic energy to the conductive material; forming non-conductive resin on the non-conductive material on which the conductive material has been printed, using a three-dimensional printer head, the non-conductive resin being (or serving as) an insulation component; and forming a connecting portion or via hole in the non-conductive resin.

According to at least another embodiment of the present invention, a method for printing electrically conductive traces on a non-conductive material includes: printing a conductive material onto a non-conductive material by transferring ultrasonic energy to the conductive material; placing a prepreg on the non-conductive material on which the conductive material has been printed; and forming a connecting portion or via hole in the prepreg.

### BRIEF DESCRIPTION OF THE DRAWINGS

The accompanying drawings, which are included to provide a further understanding of the invention and are incorporated in and constitute a part of this specification, illustrate embodiments of the invention and, together with the description, serve to explain the principles of the invention.

FIG. 1 shows examples of 1-dimensional array ultrasonic bonding tools or bonders for electrical patterning according to at least one embodiment of the present invention.

FIG. 2 shows examples of 2-dimensional array ultrasonic bonders for electrical patterning according to at least one embodiment of the present invention.

FIG. 3 shows a center started procedure for 3D-shaped multiple-layered ultrasonic voxel manufacturing according to at least one embodiment of the present invention.

FIG. 4 shows a build up procedure for 3D-shaped multiple-layered ultrasonic voxel manufacturing according to at least one embodiment of the present invention.

FIG. 5 shows a prepreg stack-up procedure for 3D-shaped multiple-layered ultrasonic voxel manufacturing according to at least one embodiment of the present invention.

FIG. 6 shows a typical ultrasonic assembly used to apply ultrasonic energy with a single bonding tool.

FIG. 7 show an example of a bonding process according to at least one embodiment of the present invention.

FIG. 8 shows an example of an insulator (resin) extrusion head.

FIG. 9 shows a force sensor according to at least one embodiment of the present invention.

FIG. 10 shows a control flow according to at least one embodiment of the present invention.

FIG. 11 shows a universal additive manufacturing packaging (UAMP) process according to at least one embodiment of the present invention.

### DETAILED DESCRIPTION OF EMBODIMENTS

The following description is of various exemplary embodiments only, and is not intended to limit the scope, applicability or configuration of the present disclosure in any way. Rather, the following description is intended to provide a convenient illustration for implementing various embodiments including the best mode. As will become apparent, various changes may be made in the function and arrangement of the elements described in these embodiments without departing from the scope of the present disclosure. Hereinafter, features of embodiments of the present invention will be described with respect to the embodiment(s) illustrated in the annexed drawings.

In the present application, the terms “print” and “bond” may be used interchangeably. In the present application, three types of procedures are disclosed for 3D-shaped multiple-layered ultrasonic voxel manufacturing: a center started procedure, a build up procedure, and a stack-up procedure. In various embodiments disclosed in the present application, ultrasonic energy is applied to bond various materials (metals, polymers, ceramics) to similar or dissimilar materials. For example, a conductive material and a non-conductive material may be bonded by applying ultrasonic energy. Feedstock materials for bonding may be in various forms such as wire, strip, foil, etc.

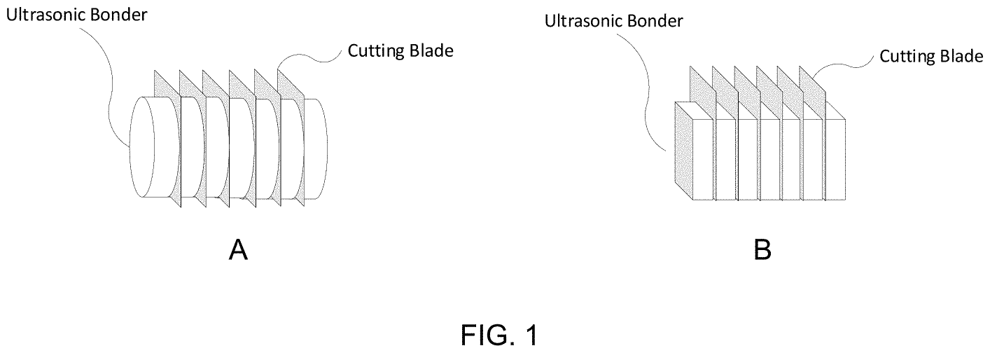

Referring to FIG. 1, a one-dimensional array of ultrasonic bonding tools, including cylindrical bonding rollers with optional cutting blades (A) or rectangular elements with optional cutting blades (B), fabricates electrical patterns on insulating substrates. Element shapes may be changed to various shapes such as a triangle, ball, or other shapes. Elements in an array are activated in various patterns, for example, in a single pattern or multiple pattern. In addition, electrical patterns can be fabricated on 2-dimensional or 3-dimensional surfaces one-by-one, multiples-by-multiple, and line-by-line, on insulating substrates. Insulating substrates can be additively printed for 3-dimensional electrical patterns.

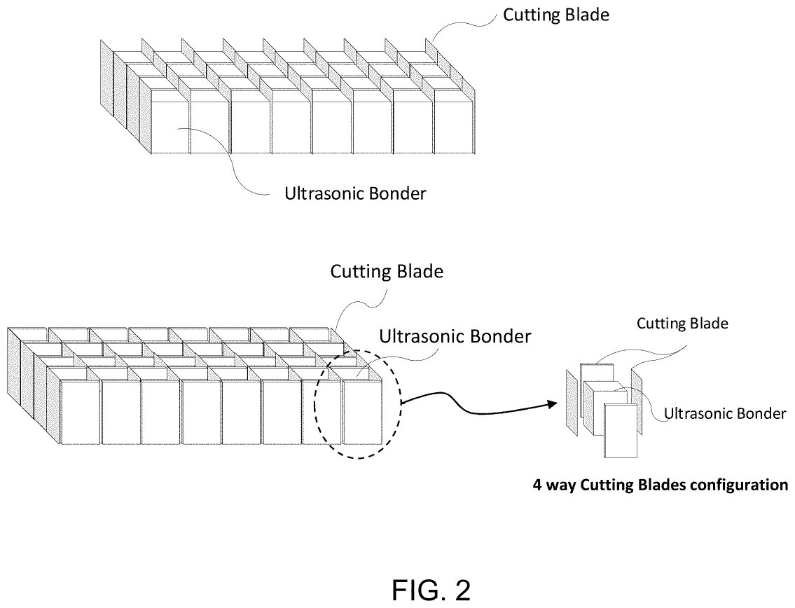

Further, various insulating materials may be additively fabricated onto the electrical patterns to build 3-dimensional PCB structures. Referring to FIG. 2, the two-dimensional array of ultrasonic bonders, including multiple bonding elements with optional selectable cutting blades, fabricates electrical patterns such that a wide area is covered in a single path. Element shapes may be changed to various shapes, for example, a triangle, ball, or other shapes. Elements in an array may be activated in various patterns including a single pattern or multiple pattern. In addition, electrical patterns may be fabricated on 2-dimensional or 3-dimensional surfaces one-by-one, multiples-by-multiple, and line-by-line, on insulating substrates. Insulating substrates may be additively printed for 3-dimensional electrical patterns. Further, various insulating materials may be additively fabricated onto the electrical patterns to build 3-dimensional PCB structures.

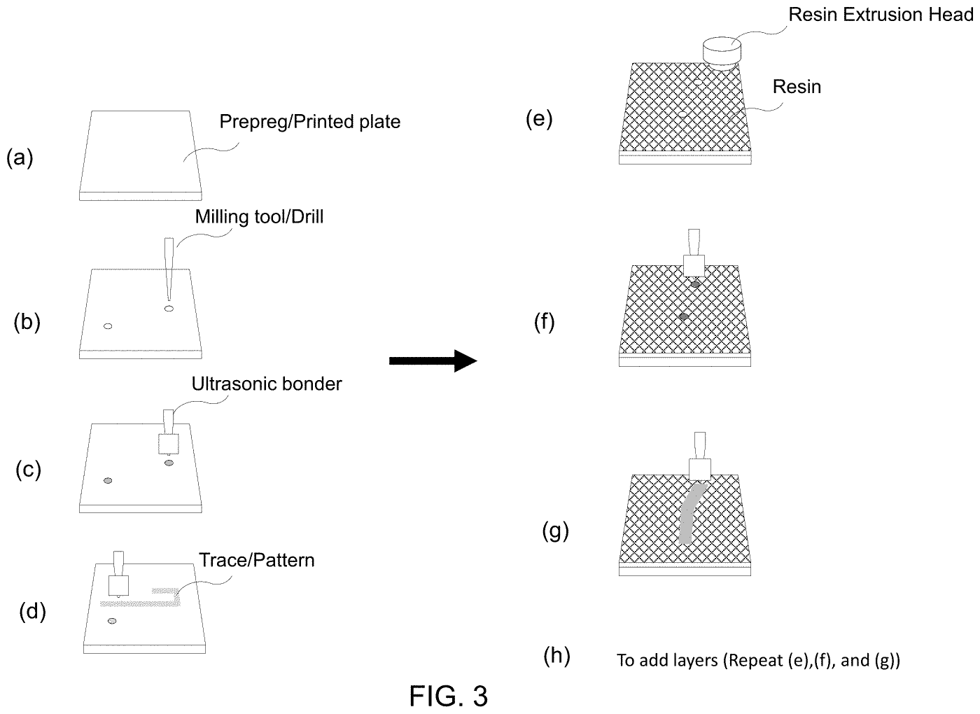

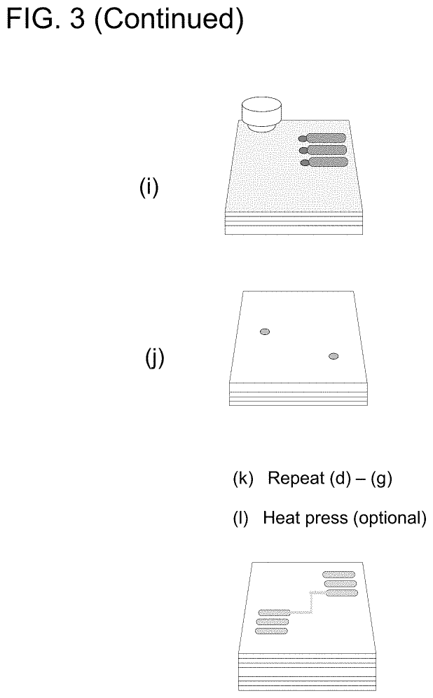

Referring to FIG. 3 (including (a) to (l)), according to at least one embodiment of the present invention, the center started procedure includes: (a) preparing (or printing) a prepreg on a base platen as a first layer that becomes a center layer after completion (the first layer may be flat or in a 3D geometry); (b) making holes for vias and other uses with a milling tool/drill (alternatively, a pre-holed prepreg may be used); (c) tightly filling the holes with conductive filler material(s); (d) printing a trace or electrical pattern with copper or other conductive material(s) on the prepreg substrate using the ultrasonic bonder; (e) making an insulation layer as a second (or next) layer by either printing/spreading insulating material(s) on the top surface of the first layer around via holes or placing a pre-holed prepreg as a second layer; (f) tightly filling the via holes of the second layer with conductive filler material(s); (g) printing a trace, pad or electrical pattern with copper or other conductive material(s) on the second layer by using the ultrasonic bonder; and (h) repeating (e), (f), and (g) to make more than two layers.

Referring to FIG. 3 (continued), on the last layer, a solder mask and then part numbers are printed with epoxy and ink by (i) printing a solder mask by the print head with insulation material(s) (for example, epoxy) to cover the entire side except soldering locations; (j) flipping the PCB to print additional layers on the other side of the PCB; (k) repeating (d)-(g) for additional layers on the flipped side of the PCB and then performing (i) for the last layer; and (l) performing heat press, which is optional, to complete the PCB.

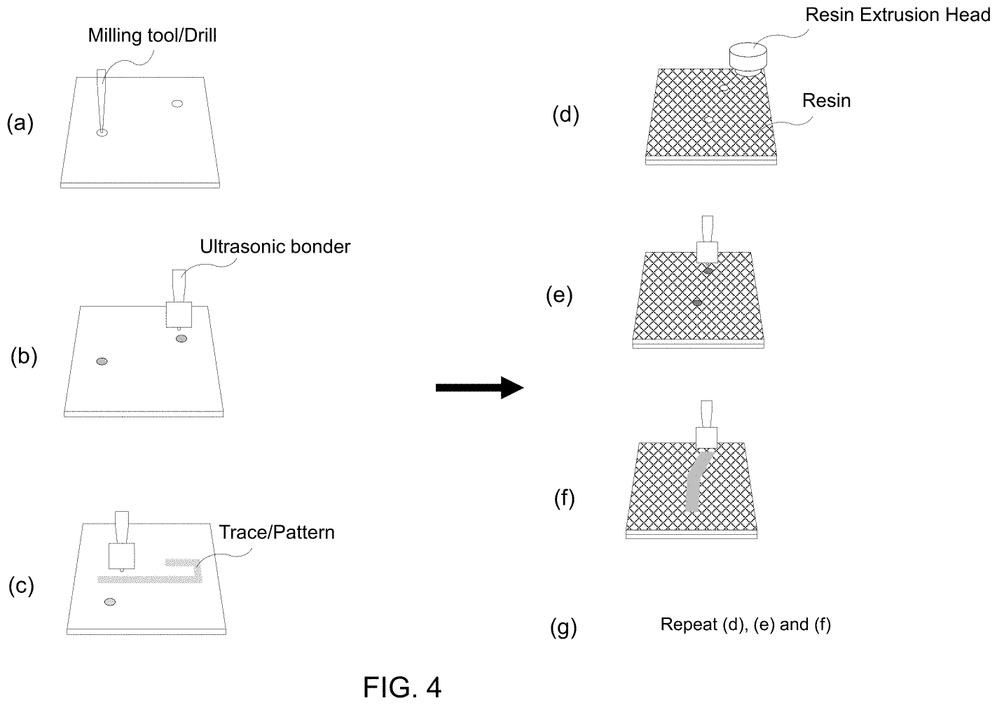

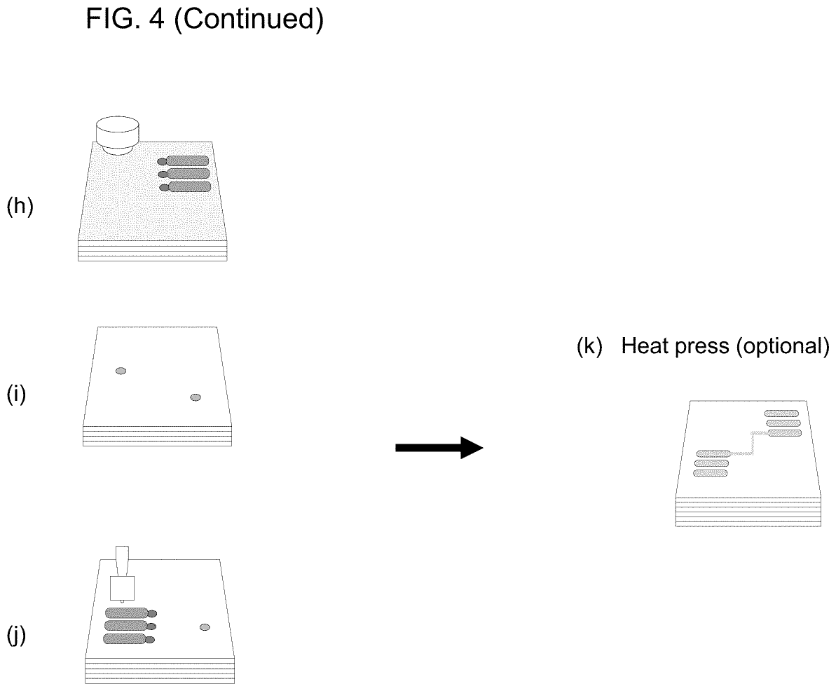

Referring to FIG. 4 (including (a) to (k)), according to at least another embodiment of the present invention, the build-up procedure includes: preparing (or printing) a prepreg on a base platen as a first layer (the first layer may be flat or in 3D geometry); (a) making holes for vias and other uses with a milling tool/drill (alternatively, a pre-holed prepreg may be used); (b) tightly filling the via holes with conductive filler material(s); (c) printing a trace or electrical pattern with copper or other conductive material(s) on the prepreg substrate using the ultrasonic bonder; (d) making an insulation layer as a second (or next) layer by either printing/spreading insulating material(s) on the top surface of the first layer around via holes or placing a pre-holed prepreg as a second layer; (e) tightly filling the via holes of the second layer with conductive filler material(s); (f) printing a trace, pad, or electrical pattern with copper or other conductive material(s) on the second layer (or newly added) by using the ultrasonic bonder; (g) repeating (d), (e), and (f) for additional layers; (h) printing solder mask to cover the last layer surface by the resin print head and printing a component (part) number; (i) flipping the printed PCB to finish the other side of the PCB without adding additional layers; (j) repeating (g) if necessary; and (k) then (optionally) performing heat press to complete PCB fabrication.

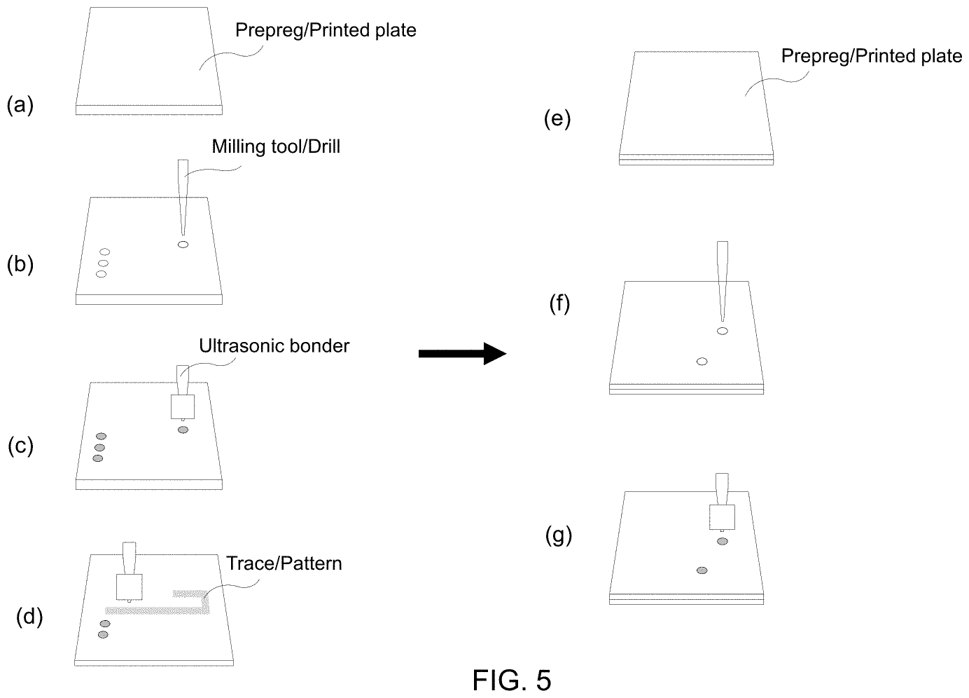

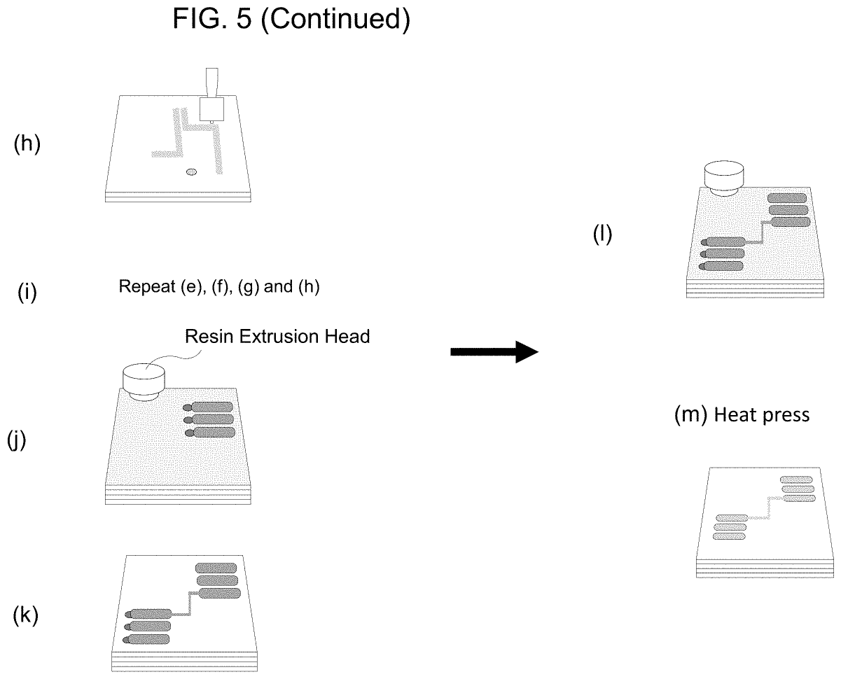

Referring to FIG. 5 (e.g., FIGS. 5(a) to 5(m)), according to at least one embodiment of the present invention, the stack-up procedure includes: (a) preparing (or printing) a prepreg on a base platen as a first layer that becomes a center layer after completion (the first layer may be flat or in 3D geometry); (b) making holes for vias and other uses with a milling tool/drill (alternatively, a pre-holed prepreg may be used); (c) tightly filling the via holes with conductive filler material(s); (d) printing a trace or electrical pattern with copper or other conductive material(s) on the prepreg substrate using the ultrasonic bonder; (e) placing a prepreg on the top surface of the first (current) layer to make a second (or next) layer; (f) making holes for vias and other uses with a milling tool/drill or a pre-holed prepreg may be used; (g) tightly filling the via holes of the layer with conductive filler material(s); (h) printing a trace, pad, or electrical pattern with copper or other conductive material(s) on the second (or newly added) layer by using the ultrasonic bonder; (i) repeating steps (e), (f), (g), and (h) for multiple layers; (j) printing solder mask to cover the surface of the last layer by the print head for solder mask and printing a component (part) number; (k) flipping the printed PCB to finish the other side of the PCB without adding additional layers; (l) printing solder mask to cover the surface of the last layer by the print head for solder mask and print a component (part) number; and (m) performing heat press to complete the PCB, which is optional.

As described above, the procedures disclosed for 3D-shaped multiple-layered PCB manufacturing according to embodiments of the present invention are non-chemical and simple to be implemented, e.g., for mass production. The ultrasonic energy is used to bond conductive materials to insulating substrates by using bonding tools shown, for example, in FIGS. 1 and 2. The ultrasonic energy may be transferred by ultrasonic power through either a sonotrode (also called “horn”) with a booster or a piezo stack without a booster. Ultrasonic bonding tools or bonder are described above referring to FIGS. 1 and 2.

In embodiments disclosed in the present application, feedstock materials for conductive and insulating (non-conductive) materials may have the following forms: wire, ribbon, foil, stripe, plate, and liquid. However, it is understood that they are not limited to these forms. A bonding tool in embodiments of the present application may have various element shapes. Because ultrasonic energy is focused on an end-tip of an element, the surface configuration of the end-tip may be important and may be in various patterns such as groove, knurling, or lattice to hold feedstock materials on the contact surface during a building process.

For non-conductive layers and solder mask layers described above, a micro sized multi-nozzle head may be used with resin and adhesive materials such as epoxy and solder mask paste. Further, automatic multiple-material feeder has a capability to control various forms of materials for conductive and non-conductive materials in forms of foils, sheet, wire, strip, filament, liquid, solder paste, solder mask paste, etc. Furthermore, the following may be used as a filler material for via holes described above: conductive materials such as pure or alloys of copper, aluminum, silver, tin, and gold, and a shape of the conductive material may be wire, ribbon, metal powder, micro sized ball, or metal sheet/foil. Moreover, holes may be filled with non-conductive material(s) as necessary.

The system may be integrated with other capabilities in-line and post nondestructive evaluation/inspection, a metrology tool for verifying correct dimensions, in-line correction during building by adding and removing materials, allowing easy swapping of tools. All functions may be integrated as a single, multifunctional head or modularized plural heads. The milling spindle for via holes and part removal is placed on the multifunctional head. Thus, a contact-based probe unit may be integrated with the multifunctional head to control the dimensional accuracy at a periodic interval preset by a user.

The system bonding process according to at least one embodiment of the present invention, which uses voxel-by-voxel ultrasonic energy transfer, is a solid state, nonthermal bonding process using ultrasonic energy. The system bonding process strongly bonds segments of material to dissimilar materials at subsurface levels through plastic deformation and/or atomic diffusion.

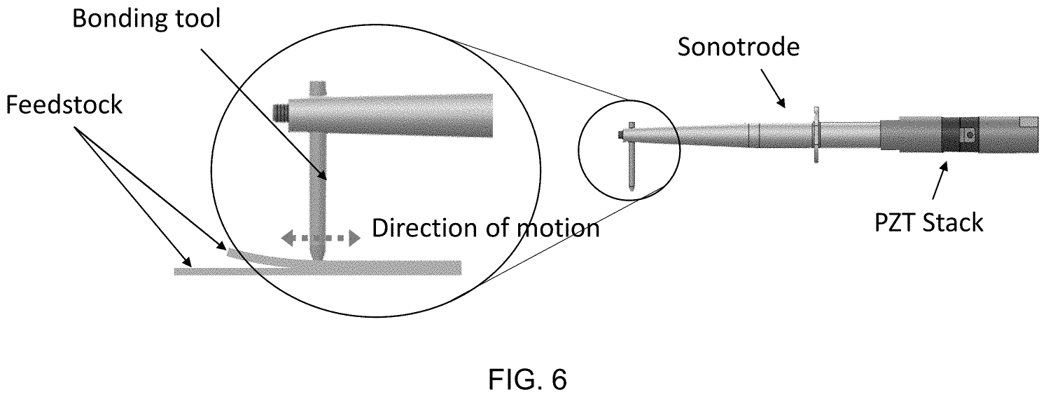

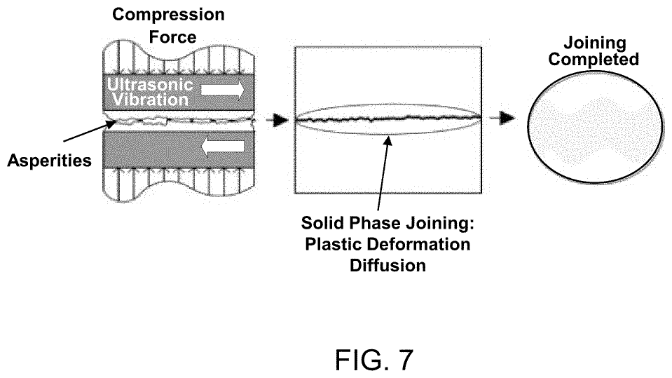

Referring to FIG. 6, when a bonding is performed, ultrasonic energy amplified by a sonotrode is applied to a bonding wedge tip. The wedge applies a compressive force and moves the segment of material being bonded with ultrasonic vibrations to join materials. Referring to FIG. 7, the applied ultrasonic energy breaks up and disperses surface oxides, generates acoustic plastic deformation that occurs in the subsurface zone between interfaces without melting, and may create perfect, void-free- and atomic-level bonding between the interfaces.

The system bonding process may consume very little energy, for example, about 2 W for 18 μm diameter gold wire. No melting/sintering is involved in the system bonding process according to various embodiments, and thus, no thermal stresses/defects are created.

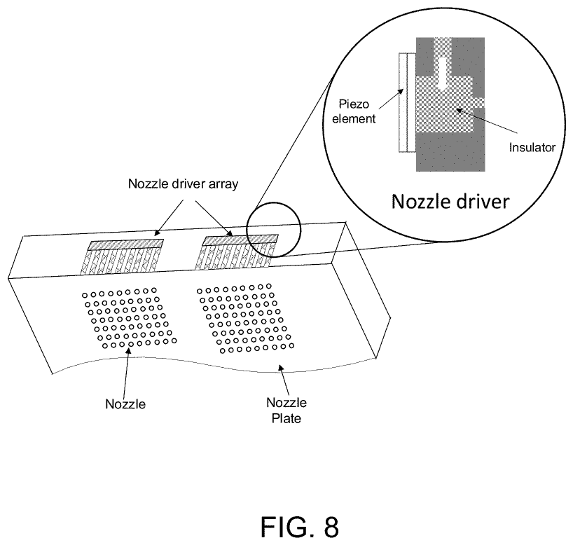

According to at least another embodiment of the present invention, an insulator 3D printing head may be used for simultaneous printing of multiple materials. FIG. 8 shows an example of an insulator extrusion head.

Referring to FIG. 8, the insulator 3D printing head is positioned on another small linear stage such as a milling tool, and a tip of the insulator 3D printing head normally positioned above a bonding tool is lowered when insulator 3D printing is needed.

A wire cutter may be used to end feedstock segments when new line segments or material change is required. For example, types of the wire cutter include a pneumatic cutter type, power scissors type with vibrating blades, and ultrasound cutting tools.

The milling tool is located on a multifunctional head with its own small linear stage such that a tip is normally positioned above a bonding tool and lowered when milling is activated. The milling tool is used during a building process to ensure proper dimensions.

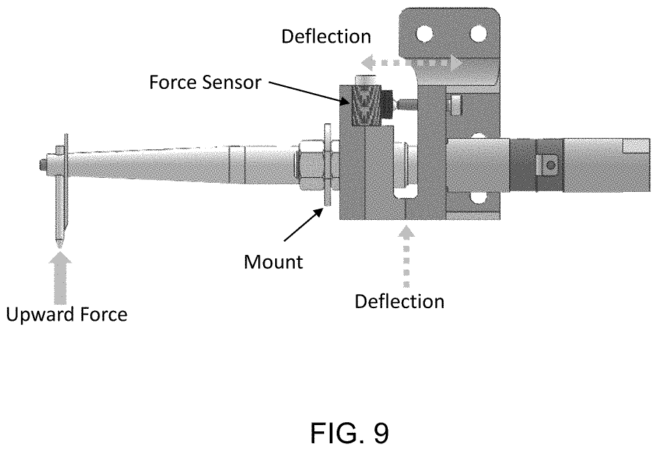

According to at least one embodiment of the present invention, a precision motion platform includes a force sensor with a force sensing mechanism because best bonding may occur when an optimal normal force is applied to feedstock. FIG. 9 shows a force sensor according to at least one embodiment of the present invention. Referring to FIG. 9, the force sensor is pushed based on upward deflection of a bonding tool. The force sensor allows for the applied bonding force to be measured in a linear manner.

According to at least another embodiment of the present invention, a force sensor is not necessary if a new motion platform Z-stage, for example, PI V-551.7x, is used. It is possible to read force through current draw in a system up to 0.1N accuracy, using the new motion platform Z-stage. Thus, using the motion platform Z-stage may simplify the system such that no analog sensor is necessary. Use of the motion platform Z-stage allows use of a moment/displacement method for readings, and simpler software may be implemented.

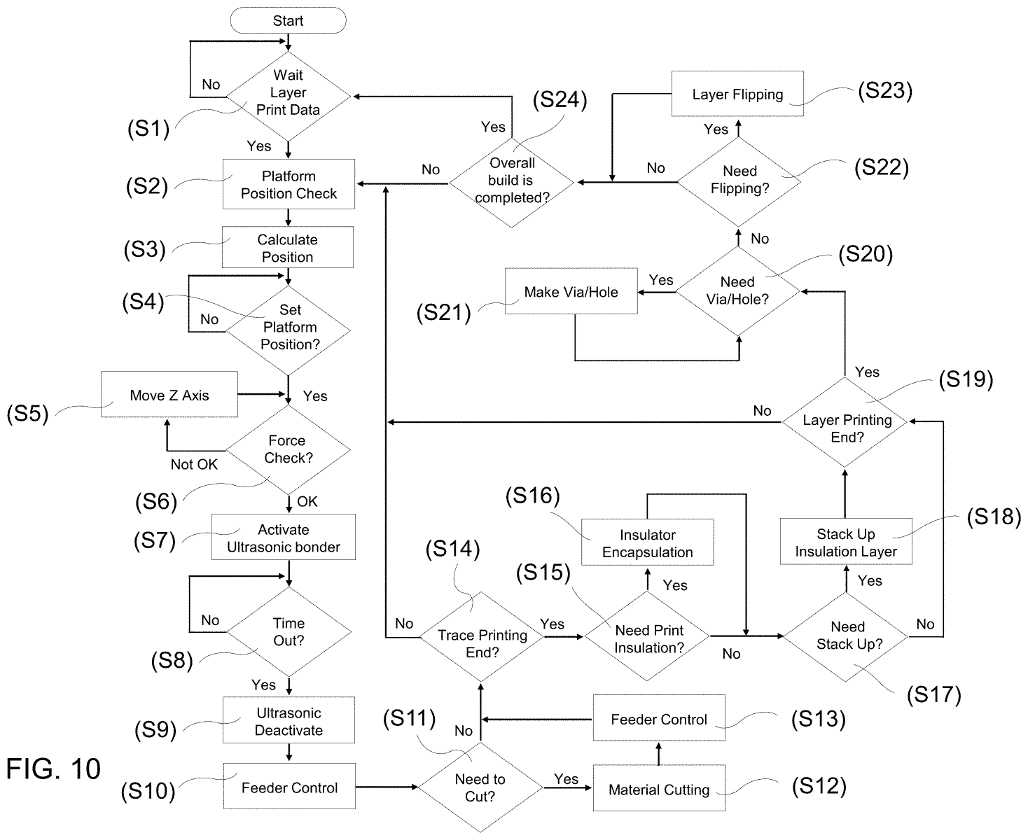

FIG. 10 shows a control flow to build an object according to at least one embodiment of the present invention. The build procedure is started when the printer receives printing data from an external device.

S1 is a step to wait for print data from an external device. If data are received from an external device (Yes), then the next procedure, S2, is performed. Otherwise (No), continue waiting for print data from an external device.

S2 is a step to check the current platform position.

S3 is a step to calculate the next print head location.

S4 is a step to move the print head to the next position until the print head reaches the correct position. When the print head reaches the position (YES), the next step, S6, is performed.

S6 is a step to check the force sensor reading to determine a preset force. When the force reaches the preset force (OK), Z-axis control is stopped and the next procedure, S7, is performed. When the checked force is not OK, S5 is performed to control the Z-axis.

S7 is a step to activate the ultrasonic bonder for an activation duration.

S8 is a step to check the activation duration. When the activation duration is reached (YES), the next step, S9, is performed. Otherwise (NO), the activation duration is checked until the activation duration is reached.

S9 is a step to deactivate the ultrasonic bonder.

S10 is a step to check a status of feedstock materials (remaining amount, etc.) and control the feeder operation.

S11 is a step to check if the feedstock needs to be cut. If the feedstock needs to be cut (Yes), the next step, S12, is performed. Otherwise (No), the next step, S14, is performed.

S12 is a step to cut the material.

S13 is a step to check a status of feedstock materials (remaining amount etc.) and control the feeder operation.

S14 is a step to determine if the end of trace build is reached. If the end of the trace build is reached (Yes), the next step, S15, is insulation layer build. If the end of the trace build is not reached (No), the next step is to build more traces on the same layer.

S15 is a step to determine the necessity of an insulation layer. If an insulation layer is necessary (Yes), then the next step, S16, is to build the insulation layer. If not (No), the next step, S17, is performed.

S16 is a step to build the insulation layer. Once the insulation layer is built, the next step, S17, is performed.

S17 is a step to determine the necessity of a stack-up process. If the stack-up process is necessary (Yes), then the next step, S18, is performed to stack prepreg (or other non-conductive material/insulation layer). If no stack-up process is necessary (No), the next step, S19, is performed.

S18 is a step to stack the prepreg (or other non-conductive material/insulation layer) up on the current layer.

S19 is a step to determine if the current layer is completed. If the current layer is completed (Yes), then the next step, S20/S21, is to make vias and holes. If the current layer has not been completed (No), then the next step is to build more layers by going back to perform S2.

S20 is a step to determine the necessity of vias and holes. If vias and holes are necessary (Yes), then the next step, S21, is to make the vias and holes. Otherwise (No), the next step, S22, is performed.

S21 is a step to make vias and holes.

S22 is a step to determine the necessity of flipping the layer. If flipping is necessary (Yes), the next step, S23, is to flip the layer. If no flipping is necessary (No), the next step, S24, is performed.

S23 is a step to flip the layer.

S24 is a step to determine if overall build is completed. If overall build is completed (Yes), either all procedures are finished or goes back to S1. If overall build is not completed (No), the procedure goes back to S2 to perform the entire procedure described above repeatedly.

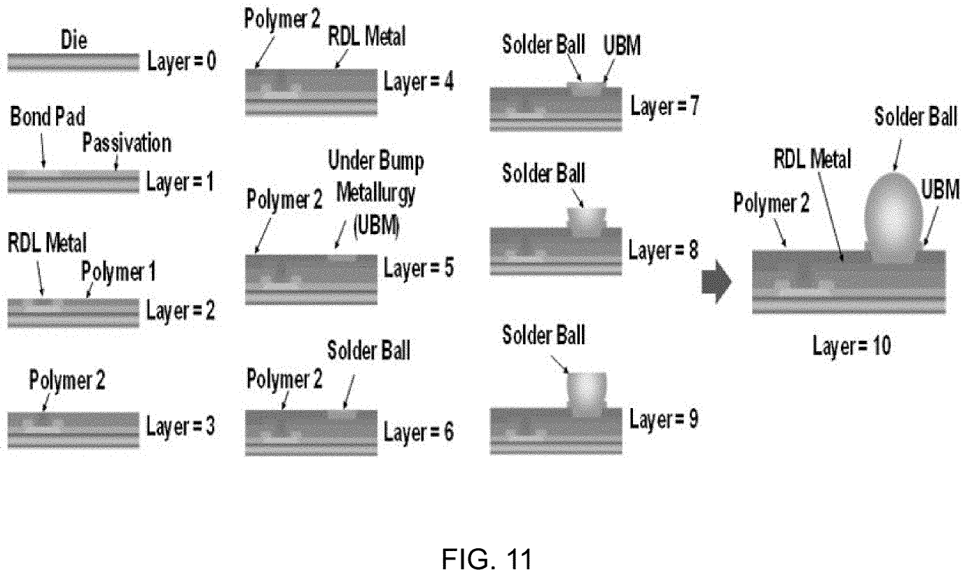

Aspects or features of embodiments of the present invention are also applicable to directly solder an active/passive electronic component on electrical patterns on the substrate. An extensive application of aspects or features of embodiments of the present invention may include additive packaging around silicon-dies by building micro-thin layers of deposition, electrical contacts, connections, insulation, filling, while ensuring protection against impact, corrosion, heat dissipation, and counterfeiting. Aspects or features of embodiments of the present invention may provide a same process to additively build all packaging components layer-by-layer on/around a semiconductor die such as contacts, pins or leads, bumps (lead or copper), electrical insulators, filling, redistribution layer (RDL) etc. with metal, polymer, and ceramics on a single platform. FIG. 11 shows a time lapse of micro-sized, multi-material printing layer-by-layer. It is noted that the layer numbers shown in FIG. 11 are nominal for illustration purposes.

Aspects of the present disclosure relate to the art and science of a multiple-layered printed circuit boards (PCB) fabrication process using ultrasonic energy for 2- and 3-dimensional PCB structures. It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A method for printing electrically conductive traces on a non-conductive material, the method comprising:
a) printing a conductive material onto a non-conductive material by transferring ultrasonic energy to the conductive material;
b) forming non-conductive resin on the non-conductive material on which the conductive material has been printed, using a three-dimensional printer head, the non-conductive resin serving as an insulation component; and
c) forming a connecting portion or via hole in the non-conductive resin.

2. The method of claim 1, further comprising fabricating a printed circuit board (PCB) by repeating a), b), and c).

3. The method of claim 2, wherein the fabricating the PCB comprises forming last non-conductive resin as a solder mask and silkscreen.

4. The method of claim 1, wherein the non-conductive material on which the conductive material is printed is a first layer and the non-conductive resin is formed as a second layer on the first layer.

5. The method of claim 4, wherein the via hole is a through hole formed through the first and second layers.

6. The method of claim 1, wherein the connecting portion or via hole is configured to be coupled to a conductive portion of another non-conductive material.

7. The method of claim 1, wherein the printing the conductive material comprises printing a trace or pattern on the non-conductive material.

8. The method of claim 7, wherein the trace or pattern is printed by the ultrasonic energy transferred by a one-dimensional tool or a two-dimensional tool.

9. The method of claim 8, wherein the one-dimensional tool or two-dimensional tool is included in a roller-type or cylindrical-type three-dimensional tool.

10. The method of claim 1, wherein:
the conductive material is printed by a sonotrode generating the ultrasonic energy; and
the forming non-conductive resin is performed by a three-dimensional resin forming device.

11. The method of claim 10, wherein a solder mask and silkscreen are made by a multi-material feeder of the three-dimensional resin forming device using the non-conductive resin.

12. The method of claim 1, further comprising cutting the printed conductive material with a cutter.

13. The method of claim 1, further comprising post processing and milling the non-conductive resin to form the connecting portion or via hole.

14. The method of claim 1, wherein the printing the conductive material onto the non-conductive material comprises guiding the conductive material on the non-conductive material.

15. The method of claim 1, further comprising maintaining tension of the conductive material to position the conductive material at a printing point on the non-conductive material while the conductive material is printed.

16. The method of claim 1, further comprising measuring and adjusting a force applied to the conductive material to maintain an optimal contact between the conductive material and the non-conductive material while the conductive material is printed.

17. The method of claim 1, wherein heating, melting, and liquifying processes are not required.

18. The method of claim 1, further comprising:
forming a three-dimensional non-conductive material by repeating a), b), and c);
printing a conductive pattern onto a surface of the three-dimensional non-conductive material; and
attaching an electronic part to the printed conductive pattern.

19. A method for printing electrically conductive traces on a non-conductive material, the method comprising:
printing a conductive material onto a non-conductive material by transferring ultrasonic energy to the conductive material;
placing a prepreg on the non-conductive material on which the conductive material has been printed; and
forming a connecting portion or via hole in the prepreg.

20. The method of claim 19, further comprising:
printing the conductive material onto the prepreg,
wherein forming the connection portion or via hole comprises forming the connecting portion or via hole in the prepreg on which the conductive material has been printed.
